(19) United States
(12) Patent Application Publication
(10) Pub. No.: US 2025/0003447 A1
(43) Pub. Date: Jan. 2, 2025

(54) FLEXIBLE ASSEMBLY AND DISPLAY DEVICE

(71) Applicant: BOE TECHNOLOGY GROUP CO., LTD., Beijing (CN)

(72) Inventor: Xinyu WANG, Beijing (CN)

(73) Assignee: BOE TECHNOLOGY GROUP CO., LTD., Beijing (CN)

(21) Appl. No.: 18/263,495

(22) PCT Filed: Apr. 28, 2022
(86) PCT No.: PCT/CN2022/089987

§ 371 Date: Jul. 28, 2023

(51) Int. Cl. F16C 11/12; H05K 5/02

(52) U.S. Cl. CPC F16C 11/12; H05K 5/0226

(57) ABSTRACT

A flexible assembly includes: a shaft body; a first rotating component rotatably connected to the shaft body; a first sliding component connected to the first rotating component; a first magnetic body fixed on the first rotating component; and a second magnetic body fixed on the first sliding component. The first magnetic body and the second magnetic body are opposite to each other in a first direction as the first sliding component moves along a first linear path relative to the first rotating component. In a case where the first sliding component moves to an end of the first linear path, a first locking force is created between the first and second magnetic bodies. In a case where the first sliding component moves to a middle of the first linear path, an attractive force between the first and second magnetic bodies is smaller than the first locking force.

### CROSS-REFERENCE TO RELATED APPLICATION

This application is a national phase entry under 35 USC 371 of International Patent Application No. PCT/CN2022/089987, filed on Apr. 28, 2022, which is incorporated herein by reference in its entirety.

### TECHNICAL FIELD

The present disclosure relates to the field of display technologies, and in particular, to a flexible assembly and a display device.

### BACKGROUND

In order to make the displayed images more clear and vivid, the size of the display device (e.g., mobile phone) is getting larger. However, the display device with a large screen has poor portability. To solve the above problem, a flexible display screen is developed, and the flexible display screen can be bent (e.g., folded) according to needs. For example, in the display device, a flexible display screen is matched with a flexible assembly to realize bending of the whole display device, so that the whole size of the display device after being bent becomes smaller.

### SUMMARY

In one aspect, a flexible assembly is provided. The flexible assembly includes a shaft body, a first rotating component, a first sliding component, a first magnetic body and a second magnetic body; the first rotating component is rotatably connected to the shaft body; the first sliding component is connected to the first rotating component and capable of reciprocating along a first linear path relative to the first rotating component, so that the first sliding component is far away from or close to the shaft body; the first magnetic body is fixed on the first rotating component, and the second magnetic body is fixed on the first sliding component; and the first magnetic body and the second magnetic body are opposite to each other in a first direction as the first sliding component moves along a first linear path relative to the first rotating component, the first direction being approximately parallel to the first linear path.

In a case where the first sliding component moves to an end of the first linear path, a first locking force is created between the first magnetic body and the second magnetic body; and in a case where the first sliding component moves to a middle of the first linear path, an attractive force between the first magnetic body and the second magnetic body is smaller than the first locking force.

In some embodiments, the first magnetic body includes a plurality of first magnetic units arranged in a second direction, and magnetic pole directions of the first magnetic units are the same as a magnetic pole direction of the first magnetic body, the second direction being approximately parallel to the first linear path.

In some embodiments, at least one first magnetic unit of the first magnetic body is detachably connected to the first rotating component.

In some embodiments, the second magnetic body includes a plurality of second magnetic units arranged in a second direction, and a magnetic pole direction of a second magnetic unit is the same as a magnetic pole direction of the second magnetic body, the second direction being approximately parallel to the first linear path.

In some embodiments, the first magnetic body and the second magnetic body each have two magnetic poles configured in a second direction, the second direction being approximately parallel to the first linear path.

In some embodiments, the first magnetic body and the second magnetic body have opposite magnetic pole directions and unequal lengths.

In some embodiments, a length of one of the first magnetic body and the second magnetic body is less than a half of a length of another of the first magnetic body and the second magnetic body.

In some embodiments, the flexible assembly further includes a third magnetic body; the third magnetic body is fixed on the first rotating component and disposed on an end of the first magnetic body in the second direction; the third magnetic body has two magnetic poles configured in the first direction, and one of the two magnetic poles is opposite to the second magnetic body in the second direction; and a magnetic pole of the third magnetic body and a magnetic pole of the second magnetic body that are opposite to each other have opposite polarities.

In some embodiments, the third magnetic body includes a plurality of third magnetic units stacked in the first direction, and a magnetic pole direction of a third magnetic unit is the same as a magnetic pole direction of the third magnetic body.

In some embodiments, the flexible assembly further includes a second rotating component and a second sliding component; the second rotating component is rotatably connected to the shaft body; the second rotating component and the first rotating component rotate in opposite directions; the second sliding component is connected to the second rotating component and capable of reciprocating along a second linear path relative to the second rotating component, so that the second sliding component is far away from or close to the shaft body.

In some embodiments, the flexible assembly further includes a fourth magnetic body and a fifth magnetic body, the fourth magnetic body is fixed on the second rotating component, and the fifth magnetic body is fixed on the second sliding component; and the fourth magnetic body and the fifth magnetic body are opposite to each other in a third direction as the second sliding component moves along the second linear path relative to the second rotating component, the third direction being approximately perpendicular to the second linear path.

In a case where the second sliding component moves to an end of the second linear path, a second locking force is created between the fourth magnetic body and the fifth magnetic body; and in a case where the second sliding component moves to a middle of the second linear path, an attractive force between the fourth magnetic body and the fifth magnetic body is smaller than the second locking force.

In some embodiments, the flexible assembly further includes a first flexible connecting component, an end of the first flexible connecting component is connected to the second rotating component, and another end of the first flexible connecting component is connected to the first sliding component.

In some embodiments, the first rotating component is provided therein with a first guiding structure matched with the first flexible connecting component, and a guiding direction of the first guiding structure is approximately parallel to the first linear path.

In some embodiments, the first flexible connecting component includes a plurality of pin shafts and a plurality of chain links, and two adjacent chain links in the plurality of chain links are connected through a pin shaft.

In some embodiments, the chain links each include a first flat limiting surface and a second flat limiting surface that are opposite and parallel to each other in an arrangement direction of the plurality of chain links.

In a case where the first flexible connecting component is in an unfolded state, a first flat limiting surface of one of the two adjacent chain links and a second flat limiting surface of another of the two adjacent chain links are able to abut against each other.

In some embodiments, in a case where the first flexible connecting component is in an unfolded state, the first flat limiting surface is approximately perpendicular to a plane where the first flexible connecting component is located.

In some embodiments, the chain links each include a first bent limiting surface and a second bent limiting surface that are opposite to each other in an arrangement direction of the plurality of chain links; and in a case where the first flexible connecting component is in a folded state, a first bent limiting surface of one of the two adjacent chain links and a second bent limiting surface of another of the two adjacent chain links are able to abut against each other.

In some embodiments, the flexible assembly further includes a second flexible connecting component, an end of the second flexible connecting component is connected to the first rotating component, and another end of the second flexible connecting component is connected to the second sliding component.

In some embodiments, the first rotating component and the second rotating component are able to synchronously rotate around the shaft body in opposite directions.

In some embodiments, the flexible assembly further includes a first drive gear wheel and a second drive gear wheel; the first drive gear wheel is linked to the first rotating component; the second drive gear wheel is linked to the second rotating component; and the first drive gear wheel and the second drive gear wheel are each pivotally connected to the shaft body, and are engaged with each other.

In some embodiments, an axis of the first rotating component rotating around the shaft body does not coincide with an axis of the first drive gear wheel rotating around the shaft body, and the first drive gear wheel is slidably connected to the first rotating component.

In some embodiments, an axis of the second rotating component rotating around the shaft body does not coincide with an axis of the second drive gear wheel rotating around the shaft body, and the second drive gear wheel is slidably connected to the second rotating component.

In some embodiments, an axis of the first rotating component rotating around the shaft body does not coincide with an axis of the first drive gear wheel rotating around the shaft body, and the first drive gear wheel is slidably connected to the first rotating component; and an axis of the second rotating component rotating around the shaft body does not coincide with an axis of the second drive gear wheel rotating around the shaft body, and the second drive gear wheel is slidably connected to the second rotating component.

In some embodiments, the first drive gear wheel includes a connecting shaft, a plurality of teeth, and a connecting plate; the connecting shaft is pivotally connected to the shaft body; the plurality of teeth are distributed in a circumferential direction of the connecting shaft; the connecting plate is fixedly connected to the connecting shaft and extending in a direction parallel to a radial direction of the connecting shaft; the first rotating component has a sliding rail, and an extending direction of the sliding rail is approximately parallel to the first linear path; and the connecting plate has a sliding block capable of sliding along the sliding rail.

In some embodiments, the connecting plate is provided therein with a limiting groove, and the limiting groove extends in the direction parallel to the radial direction of the connecting shaft; and the first rotating component further has a limiting portion capable of sliding in the limiting groove.

In some embodiments, the flexible assembly further includes a torque plate; the torque plate has a first hole and a second hole; the first drive gear wheel is pivotally connected to the first hole; and the second drive gear wheel is pivotally connected to the second hole.

In some embodiments, the torque plate is provided therein with a first opening communicated with the first hole.

In some embodiments, the torque plate is provided therein with a second opening communicated with the second hole.

In some embodiments, the torque plate is provided therein with a first opening communicated with the first hole; and the torque plate is provided therein with a second opening communicated with the second hole.

In another aspect, a display device is provided. The display device includes the flexible assembly according to any one of the embodiments and a flexible display screen. The flexible display screen is connected to the first sliding component in the flexible assembly.

### BRIEF DESCRIPTION OF THE DRAWINGS

In order to describe technical solutions in the present disclosure more clearly, accompanying drawings to be used in some embodiments of the present disclosure will be introduced briefly below. However, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, and are not limitations on actual sizes of products, actual processes of methods and actual timings of signals to which the embodiments of the present disclosure relate.

FIG. 1 is a diagram showing a display device in an unfolded state, in accordance with some embodiments;

FIG. 2 is a diagram showing a display device in a folded state, in accordance with some embodiments;

FIG. 3 is a structural diagram of a flexible assembly in FIG. 1 in an unfolded state;

FIG. 4A is a sectional view taken along the line C-C in FIG. 3;

FIG. 4B is a structural diagram of the flexible assembly in FIG. 4A in a folded state;

FIG. 4C is a structural diagram of the display device in FIG. 1 in a bent state;

FIG. 5 is a structural diagram of the display device in FIG. 1 in a bent state;

FIG. 6 is an A-direction view showing a structure of a first magnetic body and a second magnetic body in FIG. 4A;

FIG. 7 is an alterative structural diagram of FIG. 3;

FIG. 8A is an enlarged view of the region K2 in FIG. 4A;

FIG. 8B is an alternative enlarged view of the region K2 in FIG. 4A;

FIG. 9 is an alternative structural diagram of FIG. 4A.

FIG. 10 is an enlarged view of the region K1 in FIG. 9;

FIG. 11 is another alternative enlarged view of the region K2 in FIG. 4A;

FIG. 12 is a distribution diagram of magnetic induction lines in a case where a flexible assembly is in an unfolded state or a bent state, in accordance with some embodiments;

FIG. 13A is a perspective view of the flexible assembly in FIG. 9 in an unfolded state;

FIG. 13B is a perspective view of the flexible assembly in FIG. 13A in a folded state;

FIG. 14 is yet another alternative enlarged view of the region K2 in FIG. 4A;

FIG. 15 is an enlarged view of the region K3 in FIG. 14;

FIG. 16A is a structural view of a second rotating component in FIG. 7;

FIG. 16B is a structural view of a first rotating component in FIG. 7;

FIG. 16C is a structural diagram of a first sliding component in FIG. 7;

FIG. 17 is yet another alternative schematic diagram of FIG. 3;

FIG. 18 is a sectional view taken along the line D-D in FIG. 17;

FIG. 19 is a three-dimensional structural diagram of a first flexible connecting component in FIG. 17;

FIG. 20A is a sectional view taken along the line B-B in FIG. 17;

FIG. 20B is a schematic diagram of a structure in FIG. 20A in a folded state;

FIG. 21 is a structural diagram of a chain link in FIG. 19;

FIG. 22 is a schematic diagram of the first flexible connecting component in FIG. 19 in an unfolded state;

FIG. 23 is a schematic diagram of the first flexible connecting component in FIG. 19 in a folded state;

FIG. 24 is a schematic diagram of a backside of the first flexible connecting component in FIG. 19 in an unfolded state;

FIG. 25 is a sectional view taken along the line E-E in FIG. 17;

FIG. 26 is a structural diagram of a first drive gear wheel in FIG. 17;

FIG. 27 is a structural diagram of a torque plate in FIG. 25; and

FIG. 28 is a partial enlarged view of a bottom of the structure shown in FIG. 3.

### DETAILED DESCRIPTION

Technical solutions in some embodiments of the present disclosure will be described clearly and completely with reference to the accompanying drawings below. However, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, the term “comprise” and other forms thereof such as the third-person singular form “comprises” and the present participle form “comprising” throughout the specification and the claims are construed as an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the terms “a plurality of”, “the plurality of” and “multiple” each mean two or more unless otherwise specified.

In the description of some embodiments, the terms “coupled”, “connected” and derivatives thereof may be used. For example, the term “connected” may be used in the description of some embodiments to indicate that two or more components are in direct physical or electrical contact with each other. For another example, the term “coupled” may be used in the description of some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the contents herein.

The phrase “A and/or B” includes the following three combinations: only A, only B, and a combination of A and B.

The phrase “applicable to” or “configured to” used herein has an open and inclusive meaning, which does not exclude devices that are applicable to or configured to perform additional tasks or steps.

As used herein, the term such as “about”, “substantially” or “approximately” includes a stated value and an average value within an acceptable range of deviation of a particular value. The acceptable range of deviation is determined by a person of ordinary skill in the art in view of measurement in question and errors associated with measurement of a particular quantity (i.e., limitations of a measurement system). The terms “parallel”, “perpendicular” and “equal” as used herein include the stated conditions and the conditions similar to the stated conditions, and the range of the similar conditions is within the acceptable deviation range, where the acceptable deviation range is determined by a person of ordinary skill in the art in consideration of the measurement in question and the error associated with the measurement of a specific quantity (i.e., the limitation of the measurement system). For example, the term “parallel” or “approximately parallel” includes absolute parallelism and approximate parallelism, where an acceptable range of deviation of the approximate parallelism may be, for example, a deviation within 5 degrees; the term “perpendicular” or “approximately perpendicular” includes absolute perpendicularity and approximate perpendicularity, where an acceptable range of deviation of the approximate perpendicularity may also be, for example, a deviation within 5 degrees. The term “equal” or “approximately equal” includes absolute equality and approximate equality, and an acceptable range of deviation of approximate equality may be, for example, that a difference between two equals is less than or equal to 5% of any one of the two equals.

Exemplary embodiments are described herein with reference to section views and/or plan views as idealized exemplary drawings. In the accompanying drawings, thicknesses of layers and sizes of regions are enlarged for clarity. Variations in shapes with respect to the accompanying drawings due to, for example, manufacturing technologies and/or tolerances may be envisaged. Therefore, the exemplary embodiments should not be construed as being limited to the shapes of the regions shown herein, but including deviations due to, for example, manufacturing. For example, an etched region shown as a rectangle shape generally has a feature being curved. Thus, the regions shown in the accompanying drawings are schematic in nature, and their shapes are not intended to show actual shapes of regions in a device, and are not intended to limit the scope of the exemplary embodiments.

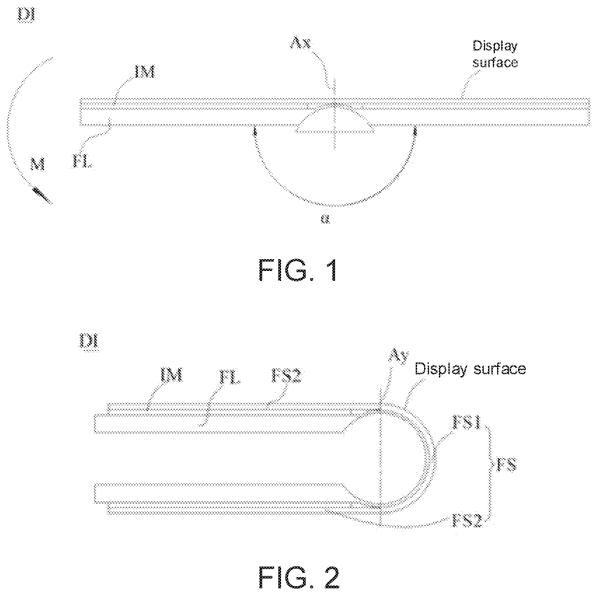

FIG. 1 is a schematic diagram of a display device in an unfolded state, in accordance with some embodiments. FIG. 2 is a schematic diagram of a display device in a folded state, in accordance with some embodiments. Referring to FIGS. 1 and 2, some embodiments of the present disclosure provide a display device DI, and a size and/or state of the display device DI is changed by curving (e.g., folding). For example, the display device DI is an electronic device capable of displaying images and being bendable (e.g., foldable). The electronic device may be a mobile phone, a tablet panel or a television.

For example, the display device DI is a foldable electronic device. For example, the display device DI may have a bending axis Ax, so that two portions of a flexible screen divided by the bending axis may be folded in half. In this case, the display device DI may be referred to as a two-fold display device. As another example, the display device DI may have a plurality of bending axes Ax. In this case, the display device DI may be referred to as a triple-fold display device, a quadruple-fold display device, a quintuple-fold display device, etc.

A relationship between a bending angle and a shape of the display device DI will be described below by taking an example in which the display device DI is a two-fold display device.

In some possible implementations, referring to FIG. 1, in a case where the display device DI is in an unfolded state, the bending angle α of the display device DI is approximately 180 degrees, which is the maximum angle that the display device DI can be unfolded. Therefore, in a case where the bending angle α of the display device DI is maximum, the display device DI has a flat display surface. Referring to FIG. 2, the display device DI is bent to be in a folded state, and the bending angle α of the display device DI is approximately 0 degrees. It can be seen that the display device DI may be bent from 0 degrees to 180 degrees. This display device DI is bent along a direction M indicated by the curved line, and the size of the bent display device DI becomes smaller, which facilitates storage.

In other possible implementations, the maximum bending angle α of the display device DI may be other values, such as 190 degrees, 200 degrees, and 210 degrees.

In still other possible implementations, the display device DI may be bent from 0 degrees to 360 degrees.

When the display device DI is bent to 0 degrees or 360 degrees, the display device DI is in a folded state; when the display device DI is bent to 180 degrees, the display device DI is in an unfolded state; and when the display device DI is bent to other angles, the display device DI is in a bent state.

With continued reference to FIG. 2, the display device DI includes a flexible assembly FL and a flexible screen FS (which is also referred to a flexible display screen FS), and the flexible assembly FL is connected to the flexible screen FS.

For example, the flexible screen FS may be an organic light-emitting diode (OLED) flexible screen FS, a quantum dot light-emitting diode (QLED) flexible screen FS, etc.

For example, the flexible assembly FL in embodiments of the present disclosure may enable local bending of the flexible screen FS. The flexible screen FS includes a plurality of bendable portions FS1 and a plurality of non-bendable portions FS2 (in FIG. 2, the flexible screen FS is divided into a bendable portion FS1 and non-bendable portions FS2 with an axis Ay as a dividing line). For example, the bendable portions FS1 and the non-bendable portions FS2 are arranged alternately and arranged at intervals. For example, there are four bendable portions FS1 and three non-bendable portions FS2. Accordingly, the flexible assembly FL may be bent at a region corresponding to the bendable portion FS1, and may not be bent at a region corresponding to the non-bendable portion FS2.

For example, the display device DI further includes an intermediate connecting component IM, the intermediate connecting component IM is disposed between the flexible assembly FL and the flexible screen FS, and the flexible assembly FL and the flexible screen FS are connected through the intermediate connecting component IM.

In some possible implementations, there may be one intermediate connecting component IM, which is of a flexible structure. For example, a portion of the intermediate connecting component IM is opposite to the bendable portion FS1 of the flexible screen FS, and another portion of the intermediate connecting component IM is opposite to the non-bendable portion FS2 of the flexible screen FS. In this way, as the flexible component FL is bent, the intermediate connecting component IM may be bent together with the flexible screen FS. In this case, the intermediate connecting component IM can support the flexible screen FS.

In other possible implementations, there may be a plurality of intermediate connecting components IM, and each intermediate connecting component IM corresponds to a non-bendable portion FS2, so that the intermediate connecting component IM can provide rigid support to the non-bendable portion of the flexible screen FS without hindering bending of the bendable portion of the flexible screen FS.

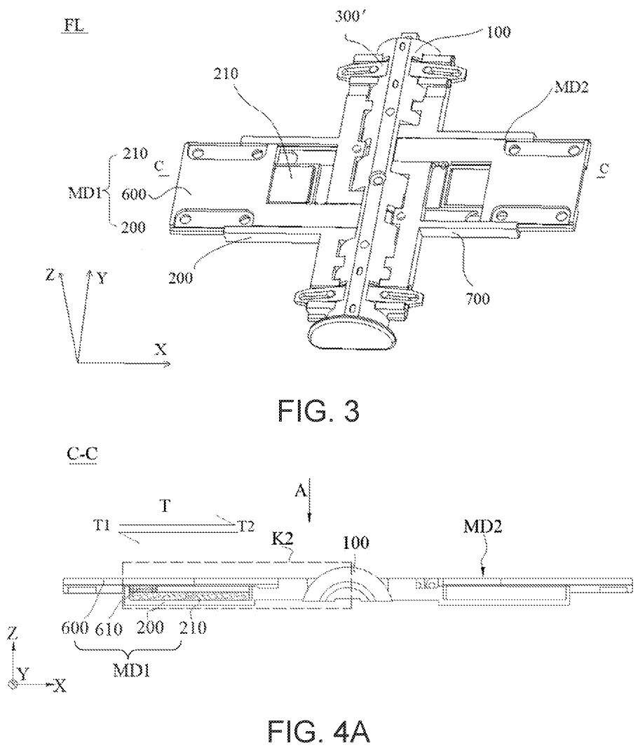

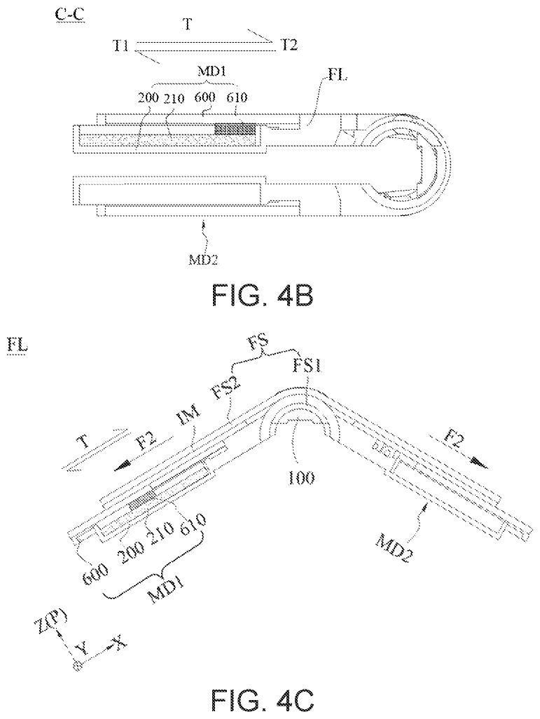

FIG. 3 is a structural diagram of the flexible assembly in FIG. 1 in an unfolded state. FIG. 4A is a sectional view taken along the line C-C in FIG. 3. FIG. 4B is a structural diagram of the flexible assembly in FIG. 4A in a folded state. FIG. 4C is a structural diagram of the display device in FIG. 1 in a bent state. Referring to FIGS. 3 and 4A to 4C, some embodiments of the present disclosure provide the flexible assembly FL, and the flexible assembly FL includes a shaft body 100 and a first module MD1. The first module MD1 may rotate relative to the shaft body 100. The first module MD1 may be connected to a non-bendable portion FS2 of the flexible display screen FS in FIG. 1, and rotate together with the non-bendable portion FS2 of the flexible display screen FS. For example, the flexible display screen FS includes a plurality of non-bendable portions FS2 (for example, two non-bendable portions FS2, and as another example, three and more non-bendable portions FS2), which are spaced apart by bending portion(s) FS1. Accordingly, the flexible assembly FL may further include a second module MD2. Based on this, one of two adjacent non-bendable portions FS2 of the flexible display screen FS is connected to the first module MD1, and the other is connected to the second module MD2.

The shaft body 100 has an axis, and the axis is a virtual straight line and is approximately parallel to an extending direction of the shaft body 100. For example, the shaft body 100 may include a shaft core and a bracket to mount the shaft core. The shaft core may be a cylinder, and a central axis of the shaft core is used as the axis of the shaft body 100. The shaft core and the bracket may be of an integral structure. The shaft body 100 may be of a rigid structure, and may be made of alloy steel (such as stainless steel or die steel) or amorphous alloy.

For example, the shaft body 100 has a first side and a second side that are opposite to each other in a radial direction of the shaft body 100. For convenience of the following description, in a case where the flexible assembly is in an unfolded state, a structure of the flexible assembly FL located on the first side of the shaft body 100 is referred to as the first module MD1, and a structure of the flexible assembly FL located on the second side of the shaft body 100 is referred to as the second module MD2. In addition, the second module MD2 may be of a rigid structure or a flexible structure. Of course, the positions of the first module MD1 and the second module MD2 relative to the shaft body 100 may be interchanged.

For example, the second module MD2 may be of a structure approximately the same as the first module MD1, and the second module MD2 and the first module MD1 are symmetrically connected to the two sides of the shaft body 100. Of course, the second module MD2 may also be of a flexible structure different from the first module MD1, thereby providing rigid support for the flexible screen FS connected thereto and driving the flexible screen FS to be bent. That is, both the first module MD1 and the second module MD2 of the flexible assembly FL can be bent around the shaft body 100.

For example, the second module MD2 may also be of a rigid structure, thus providing rigid support only for the flexible screen FS. That is, the first module MD1 of the flexible assembly FL can be bent around the shaft 100, and the second module MD2 cannot be bent around the shaft 100.

The first module MD1 may include a first rotating component 200, a first sliding component 600, a first magnetic body 210 and a second magnetic body 610.

The first rotating component 200 is rotatably connected to the shaft body 100. For example, the first rotating component 200 can rotate around the axis of the shaft body 100. For example, the first rotating component 200 is directly connected to the shaft body 100. For example, the first rotating component 200 has a mounting hole, and the shaft core of the shaft body 100 may be mounted into the mounting hole. As another example, the first rotating component 200 is indirectly connected to the shaft body 100. For example, the first rotating component 200 may be connected to the shaft body 100 through a rotating connection component 300′ (e.g., a first drive gear wheel 300 hereinafter). The rotating connection component may be hinged (e.g., pivoted) to the shaft body 100, and fixedly or slidably connected to the first rotating component 200, so as to enable the first rotating component 200 to rotate relative to the shaft body 100. The rotating connection component 300′ is pivotally connected to the shaft body 100, which means that the rotating connection component 300′ may be rotatably connected to the shaft body 100 through an axle hole structure. For example, a hole of the axle hole structure is disposed on the shaft body 100, and an axle of the axle hole structure is contained in the rotating connection component 300′. Of course, the positions of the axle and the hole may be reversed.

As for the material of the first rotating component 200, reference may be made to the material of the shaft body 100. Of course, materials of the first rotating component 200 and the shaft body 100 may be the same, or may be different.

For convenience of the following description, an XYZ Cartesian coordinate system is established by taking the axis of the shaft body 100 as the Y-axis, a length direction of the first rotating component 200 as the X-axis, and a thickness direction of the first rotating component 200 as the Z-axis. It will be understood that as the first rotating component 200 rotates, the X-axis and Z-axis rotate accordingly.

The first sliding component 600 may be slidably coupled to the first rotating component 200. The first sliding component 600 can reciprocate along a first linear path T (approximately parallel to the X axis) relative to the first rotating component 200, such that the first sliding component 600 moves away from or close to the shaft body 100. Therefore, the first sliding component 600 performs a combined rotation and sliding motion relative to the shaft body 100. In a process of the first rotating component 200 rotating around the shaft body 100 to change from an unfolded state to a folded state, the first sliding component 600 gradually moves towards the shaft body 100; and in a process of the first rotating component 200 rotating around the shaft body 100 to change from a folded state to an unfolded state, the first sliding component 600 moves in an opposite direction (i.e., moves away from the shaft body 100).

For example, the first sliding component 600 and the first rotating component 200 are opposite to each other in a first direction P (a direction indicated by the Z-axis of the XYZ Cartesian coordinate system). For example, the first sliding component 600 is located on a upper side of the first magnetic component 210 (in the direction indicated by the Z-axis), and of course the positions of the two may be interchanged. As another example, the first sliding component 600 is located on a lower side of the first magnetic component 210 (in a direction indicated by the Y-axis), and of course, positions of the two may be interchanged.

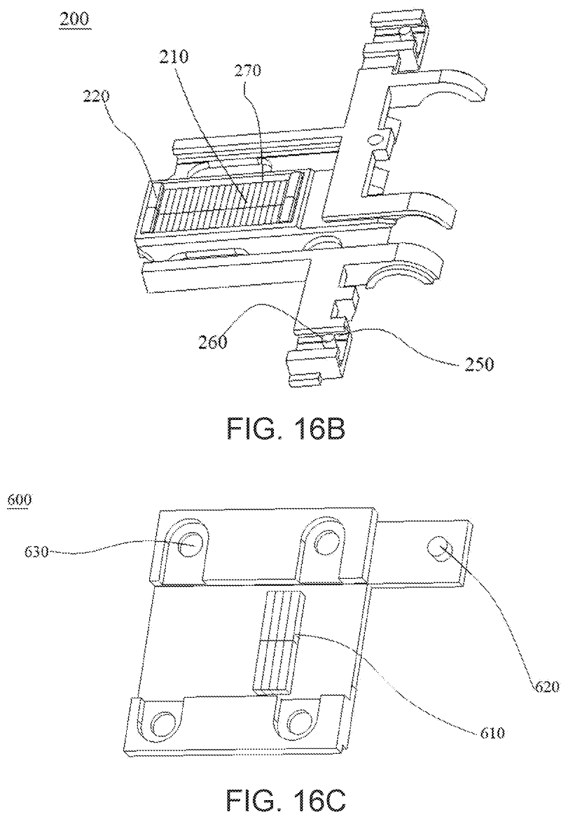

For example, the first rotating component 200 and the first sliding component 600 are slidably connected through a slot structure. For example, the first rotating component 200 is provided therein with a sliding groove 270 (shown in FIG. 16B), and the first sliding component 600 is located in the sliding groove 270 and can slide along the sliding groove 270. As another example, the first sliding component 600 is provided therein with a sliding slot, and the sliding slot and the first rotating component 200 constitute a sliding pair, thereby realizing a relative sliding between the first sliding component 600 and the first rotating component 200.

As for a material of the first sliding component 600, reference may be made to the material of the shaft body 100. Of course, materials of the first sliding component 600 and the shaft body 100 may be the same, or may be different.

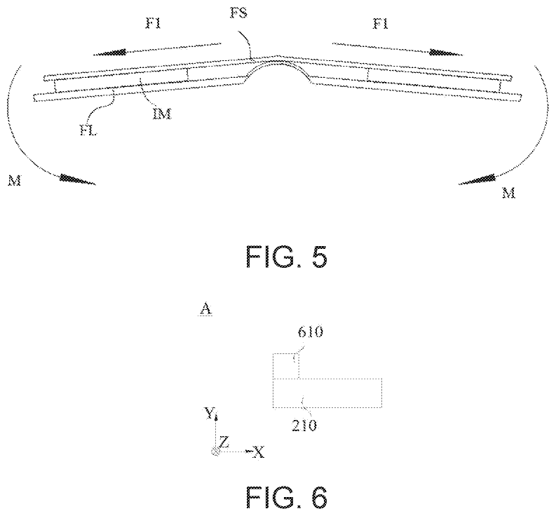

FIG. 5 is a structural diagram of the display device in FIG. 1 in a bent state. In some possible implementations, referring to FIG. 5, it is assumed that the flexible display screen FS is fixedly connected to the first rotating component 200. Then, in the flexible display screen FS, the non-bendable portion FS2 is fixed by the first rotating component 200 and can rotate only with the rotation of the first rotating component 200. Since bending radii of the flexible display screen FS and the flexible assembly FL are different, in the process of the display device DI changing from an unfolded state to a folded state, the bendable portion FS1 of the flexible display screen FS may be pulled by the non-bendable portion FS2, i.e., subjected a tensile force F1, which may cause the display screen FS to be easily damaged.

In this embodiment, the first sliding component 600 slides relative to the first rotating component 200, and the first sliding component 600 is fixed to the flexible display screen FS. The bendable portion FS1 of the flexible display screen FS can slide along the first linear path T. In the process of the display device changing from an unfolded state to a folded state, the bendable portion FS1 of the flexible display panel FS moves toward the shaft body 100, so that slip compensation is realized (i.e., the difference between the bending radii of the flexible assembly FL and the flexible display panel FS is compensated). In this case, a tensile force applied to the bendable portion FS1 of the flexible display screen FS is denoted as F2, and the tensile force F2 is much smaller than the tensile force F1, so that the tensile force F2 may be ignored, and in turn the above problem is solved.

With continued reference to FIGS. 4A to 4C, the first magnetic body 210 may include one or a combination of a permanent magnet and an electromagnet. The first magnetic body 210 is fixed on the first rotating component 200, which means that there is no relative displacement between the first magnetic body 210 and the first rotating component 200. For example, the first magnetic body 210 may be mounted to the first rotating component 200 by an assembly method such as bonding (i.e., bonding with an adhesive) or clamping.

Similarly, the second magnetic body 610 may include one or a combination of a permanent magnet and an electromagnet. Types of the second magnetic body 610 and the first magnetic body 210 may be the same or different. The second magnetic body 610 is fixed to the first sliding component 600, which means that there is no relative displacement between the second magnetic body 610 and the first sliding component 600, and as for the assembly method of the two, reference may be made to the above description.

As the first sliding component 600 moves (i.e., slides back and forth) along the first linear path T relative to the first rotating component 200, the first magnetic body 210 and the second magnetic body 610 are opposite to each other in the first direction P, which means that orthographic projections of the first magnetic body 210 and the second magnetic body 610 on a plane (a virtual plane) perpendicular to the first direction P at least partially coincide. That is, the first magnetic body 210 and the second magnetic body 610 may be distributed in the first direction P. The first direction P is approximately perpendicular to the first linear path T. The first direction P may be any direction in a YZ plane of the XYZ coordinate system. For example, in FIG. 4A, the first direction P is the direction indicated by the Z-axis, and accordingly, a plane perpendicular to the first direction P is an XY plane. Based on this, in the process of the display device switching between an unfolded state and a folded state, an orthographic projection of at least part (e.g., all or a part) of the second magnetic body 610 on the XY plane and an orthographic projection of the first magnetic body 210 on the XY plane can always have a certain overlapping region. FIG. 6 is an A-direction view showing a structure of the first magnetic body and the second magnetic body in FIG. 4A. As another example, referring to FIG. 6, the first direction P may also be a Y direction.

Thus, in the sliding process of the first sliding component 600 relative to the first rotating component 200, the first magnetic body 210 and the second magnetic body 610 always have an interaction force therebetween. The interaction force between the first magnetic body 210 and the second magnetic body 610 does not change abruptly from the existence to the nonexistence.

For example, in the sliding process of the first sliding component 600 relative to the first rotating component 200, the first magnetic body 210 and the second magnetic body 610 always have an attractive force therebetween. For example, as the first sliding component 600 slides toward the shaft body 100, the attractive force between the first magnetic body 210 and the second magnetic body 610 gradually decreases; thus, when the display device is in a folded state, the first sliding component 600 and the first rotating component 200 may be locked by the first magnetic body 210 and the second magnetic body 610. As another example, as the first sliding component 600 slides toward the shaft body 100, the attractive force between the first magnetic body 210 and the second magnetic body 610 gradually increases; thus, when the display device is in an unfolded state, the first sliding component 600 and the first rotating component 200 may be locked by the first magnetic body 210 and the second magnetic body 610. Herein, when the first sliding component 600 and the first rotating component 200 are locked, the attractive force between the first magnetic body 210 and the second magnetic body 610 is referred to as a locking force. As another example, as the first sliding component 600 slides toward the shaft body 100, the attractive force between the first magnetic body 210 and the second magnetic body 610 gradually decreases and then gradually increases; thus, when the display device is in an unfolded state and a folded state, the first sliding component 600 and the first rotating component 200 may be locked. Accordingly, as the first sliding component 600 slides away from the shaft body 100, the attractive force between the first magnetic body 210 and the second magnetic body 610 may gradually increases, gradually decreases, or gradually decreases and then gradually increases. In this way, it may be possible to avoid external force damage to the flexible display device DI caused by overexertion, and in turn prolong the service life of the flexible display device DI. In addition, the gradual change of the attractive force can improve the usage experience of the user.

For another example, as the relative position of the first sliding component 600 and the first rotating component 200 is changed, the interaction force between the first magnetic body 210 and the second magnetic body 610 may be changed from an attractive force to a repulsive force. For example, as the first sliding component 600 slides toward the shaft body 100, the interaction force between the first magnetic body 210 and the second magnetic body 610 may be an attractive force, then gradually changed to a repulsive force, and then changed to an attractive force. Based on the above, the attractive force between the first magnetic body 210 and the second magnetic body 610 gradually decreases and then gradually increases.

Referring to FIGS. 4A and 4B, in a case where the first sliding component 600 moves to an end of the first linear path T (the first linear path T has ends, i.e., from a first end T1 to a second end T2, or from the second end T2 to the first end T1), a first locking force is created between the first magnetic body 210 and the second magnetic body 610. For example, when the first sliding component 600 slides to the end T2 of the first linear path T proximate to the shaft body 100, the flexible assembly FL is in an unfolded state, and the first magnetic body 210 and the second magnetic body 610 can create a closed magnetic field therebetween and then attract each other, so as to create the first locking force (hereinafter denoted as Q1) therebetween. When the first sliding component 600 slides to the end T1 of the first linear path T away from the shaft body 100, the flexible assembly FL is in a folded state, and the first magnetic body 210 and the second magnetic body 610 can create a closed magnetic field therebetween and attract each other, so as to create a first locking force (hereinafter denoted as Q2) therebetween. For another example, when the first sliding component 600 slides to the end T2 of the first linear path T proximate to the shaft body 100, the first locking force Q1 is formed between the first magnetic body 210 and the second magnetic body 610; and when the first sliding component 600 slides to the end T1 of the first linear path T away from the shaft body 100, the first locking force Q2 is not created between the first magnetic body and the second magnetic body. For another example, the first locking force Q1 is not created between the first magnetic body 210 and the second magnetic body 610, but only the first locking force Q2 is created between the first magnetic body 210 and the second magnetic body 610. Therefore, in the present disclosure, the first magnetic body 210 and the second magnetic body 610 are used as locking mechanisms to create the first locking force Q2 and/or the first locking force Q1, which is convenient for locking the first sliding component 600 at a corresponding position, so that the flexible assembly FL maintains in a corresponding state.

For example, the first locking force Q1 and the first locking force Q2 may be approximately equal, or may not be equal.

Referring to FIG. 4C, when the first sliding component 600 moves to a middle of the first linear path T, the flexible assembly FL is in a bent state, the magnetic field created by the first magnetic body 210 and the second magnetic body 610 is not complete, and the attraction force is small. That is, the attraction force between the first magnetic body 210 and the second magnetic body 610 is less than the first locking force Q1 or the first locking force Q2. In this case, the first sliding component 600 slides relative to the first magnetic body 210, so as to ensure that the attraction force exists between the first magnetic body 210 and the second magnetic body 610, and the flexible assembly FL may be bent freely under a small acting force. The effects achieved by this embodiment are approximately the same as the effects achieved by the above embodiments, which will not be repeated here.

In some possible implementations, the first magnetic body 210 of the flexible assembly FL is disposed on a surface of the first rotating component 200 opposite to the first sliding component 600, and the second magnetic body 610 is disposed on a surface of the first sliding component 600 opposite to the first rotating component 200. In this way, a large acting force can be created between the first magnetic body 210 and the second magnetic body 610.

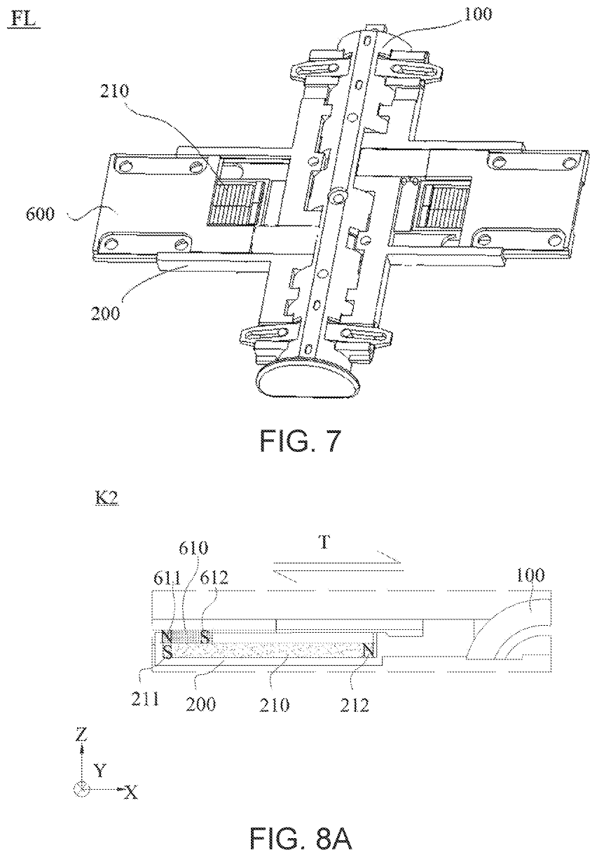

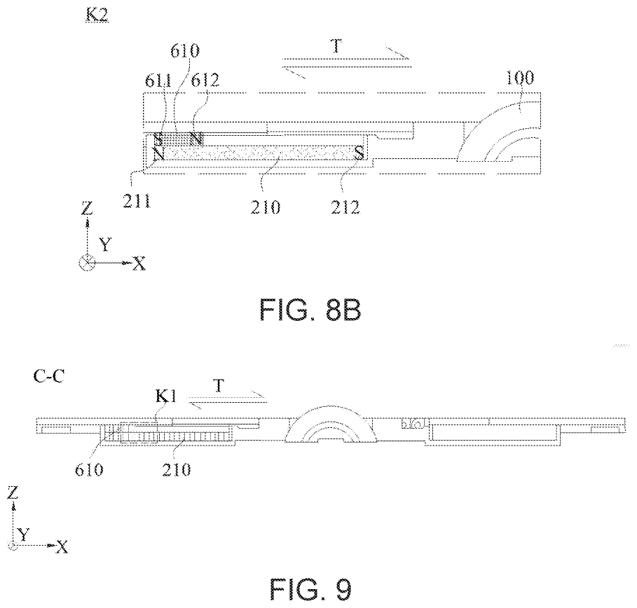

FIG. 7 is an alternative structural diagram of FIG. 3. FIG. 8A is an enlarged view of the region K2 in FIG. 4A. FIG. 8B is an alternative enlarged view of the region K2 in FIG. 4A. Referring to FIGS. 7, 8A and 8B, in some embodiments, the first magnetic body 210 and the second magnetic body 610 of the flexible assembly FL each have two magnetic poles configured in a second direction X. The second direction X is approximately parallel to the first linear path T. Therefore, an interaction force is created between the first magnetic body 210 and the second magnetic body 610.

For convenience of the following description, the two magnetic poles of the first magnetic body 210 are respectively denoted as a first magnetic pole 211 and a second magnetic pole 212, the first magnetic pole 211 is a magnetic pole at an end of the first magnetic body 210 away from the shaft body 100, and the second magnetic pole 212 is a magnetic pole at an end of the first magnetic body 210 proximate to the shaft body 100. The two magnetic poles of the second magnetic body 610 are denoted as a third magnetic pole 611 and a fourth magnetic pole 612, the third magnetic pole 611 is a magnetic pole at an end of the second magnetic body 610 away from the shaft body 100, and the fourth magnetic pole 612 is a magnetic pole at an end of the second magnetic body 610 proximate to the shaft body 100.

For example, the first magnetic body 210 and the second magnetic body 610 have opposite magnetic pole directions. That is, the first magnetic pole 211 is opposite in polarity to the third magnetic pole 611, and the second magnetic pole 212 is opposite in polarity to the fourth magnetic pole 612. For example, referring to FIG. 8A, the first magnetic pole 211 is an S pole, and the second magnetic pole 212 is an N pole; and the third magnetic pole 611 is an N pole, and the fourth magnetic pole 612 is an S pole. For another example, referring to FIG. 8B, the first magnetic pole 211 is an N pole, and the second magnetic pole 212 is an S pole; and the third magnetic pole 611 is an S pole, and the fourth magnetic pole 612 is an N pole. Therefore, an attractive force is created between the first magnetic body 210 and the second magnetic body 610.

For example, lengths of the first magnetic body 210 and the second magnetic body 610 are not equal. For example, referring to FIG. 8A, the length of the first magnetic body 210 is greater than the length of the second magnetic body 610. For another example, the length of the second magnetic body 610 is greater than the length of the first magnetic body 210. In this way, the second magnetic body 610 may slide back and forth on the first magnetic body 210, thus creating a large attractive force.

For example, a length of one of the first magnetic body 210 and the second magnetic body 610 of the flexible assembly FL is less than a half of a length of another of the first magnetic body 210 and the second magnetic body 610 of the flexible assembly FL. For example, the length of the second magnetic body 610 is less than a half of the length of the first magnetic body 210. For another example, the length of the first magnetic body 210 is less than a half of the length of the second magnetic body 610.

The interaction force (e.g., the attractive force) between the first magnetic body 210 and the second magnetic body 610 in the display device may be tested through a torsion test. The test is to fix an end of a display device to be tested and bend another end of the display device to be tested, so that the display device to be tested is simulated to change from an unfolded state to a bent state and change from a bent state to an unfolded state, and a suitable locking force of the display device to be tested is tested. If the locking force is too large, it requires a large force to change the unfolded state or the bent state of the locking device, which reduce the experience of the users; in addition, if the locking force is too small, it cannot be guaranteed to maintain the corresponding unfolded state and the bent state. Therefore, in the test, an estimated torsion value is given firstly, and then the locking force of the display device to be tested needs to be adjusted if the state of the display device to be tested cannot be changed. In some implementations, the locking mechanism for locking the first rotating component 200 and the first sliding component 600 in the flexible assembly FL may use a spring to provide the locking force, and the locking force generated by the spring is a fixed value and generally cannot be adjusted. If the locking force is to be adjusted, it will need to replace the spring or to change the pre-compression amount of the spring.

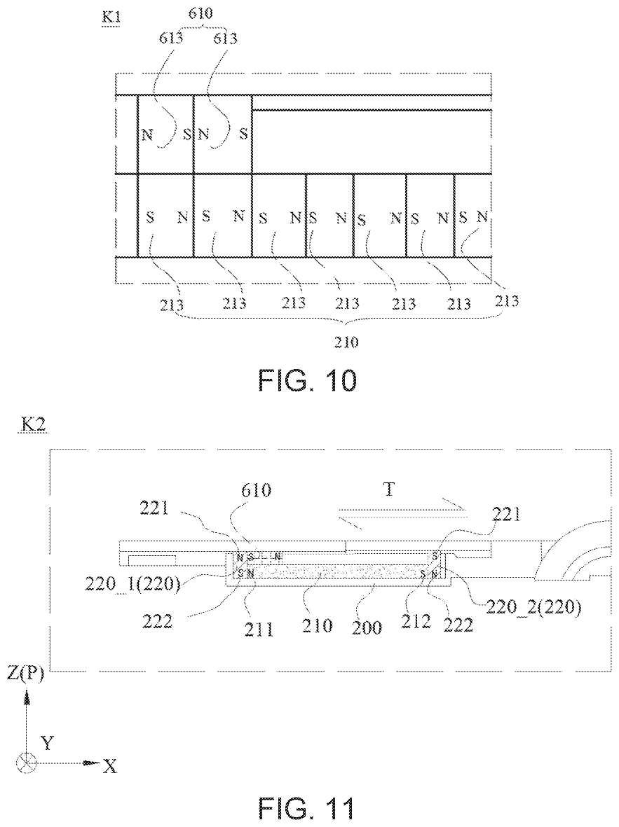

FIG. 9 is an alternative structural diagram of FIG. 4A. FIG. 10 is an enlarged view of the region K1 in FIG. 9. Referring to FIGS. 9 to 10, in some embodiments, the first magnetic body 210 of the flexible assembly FL includes a plurality of first magnetic units 213 arranged in the second direction X, and a magnetic pole direction of a first magnetic unit 213 (e.g., each first magnetic unit 213) is the same as a magnetic pole direction of the first magnetic body 210. For example, the magnetic pole direction of the first magnetic unit 213 is that an S pole is at a left end and an N pole is at a right end (this magnetic pole direction is denoted below as S˜N), and the magnetic pole direction of the first magnetic unit 213 is S˜N. For another example, the magnetic pole direction of the first magnetic unit 213 is that the S pole is at the right end and the N pole is at the left end (this magnetic pole direction is denoted below as N˜S), and the magnetic pole direction of the first magnetic unit 213 is N˜S. In this way, a magnetic field created by the plurality of first magnetic units 213 may be similar to a magnetic field created by a bar magnet. The magnitude of the attractive force between the first magnetic body 210 and the second magnetic body 610 may be adjusted by changing the number of the second magnetic units 613.

For example, at least one first magnetic unit 213 in the first magnetic body 210 of the flexible assembly FL is detachably connected to the first rotating component 200. For example, in the first magnetic body 210, each first magnetic unit 213 and the first rotating component 200 may be connected together by a detachable assembly manner such as hot-melt adhesive bonding or clamping. For another example, in the first magnetic body 210, some of the first magnetic units 213 are mounted on the first rotating component 200 by a detachable assembly manner, and other first magnetic units 213 are fixed on the first rotating component 200 and are not detachable. This facilitates rapid mounting and dismounting of some of the first magnetic units 213 to and from the first rotating component 200, thereby rapidly adjusting the number of the first magnetic units 213 to adjust the first locking force; in addition, the disassembled first magnetic unit 213 is generally not damaged and may be reused.

For example, the flexible assembly FL may include a plurality of (e.g., two or more) first magnetic bodies 210 as described above, which are arranged in the direction indicated by the Y-axis.

With continued reference to FIGS. 9 to 10, in some embodiments, the second magnetic body 610 of the flexible assembly FL includes a plurality of second magnetic units 613 arranged in the second direction X, and a magnetic pole direction of a second magnetic unit 613 (e.g., each second magnetic unit 613) is the same as a magnetic pole direction of the second magnetic body 610. For example, the magnetic pole direction of the second magnetic unit 613 is that an S pole is at a left end and an N pole is at a right end (this magnetic pole direction is denoted below as S˜N), and the magnetic pole direction of the second magnetic unit 613 is S˜N. For another example, the magnetic pole direction of the second magnetic unit 613 is that the S pole is at the right end and the N pole is at the left end (this magnetic pole direction is denoted below as N˜S), and the magnetic pole direction of the second magnetic unit 613 is N˜S. In this way, a magnetic field created by the plurality of second magnetic units 613 may be similar to a magnetic field created by a bar magnet. The effects achieved by the embodiment are approximately the same as the effects achieved by the above embodiments, which will not be repeated here.

For another example, at least one of the plurality of second magnetic units 613 of the flexible assembly FL may be detachably connected to the first sliding component 600. The assembly manner of the two may refer to the above embodiments, and details are not repeated here.

For example, the flexible assembly FL may include a plurality of (e.g., two or more) second magnetic bodies 610 as described above arranged in the direction indicated by the Y-axis. Each second magnetic body 610 is positioned opposite to a first magnetic body 210 in the direction indicated by the Y-axis.

FIG. 11 is another alternative enlarged view of the region K2 in FIG. 4A. Referring to FIG. 11, in some embodiments, the flexible assembly FL further includes a third magnetic body 220. Similarly, the third magnetic body 220 may be one or a combination of more of a permanent magnet, an electromagnet and the like.

In some possible implementations, the third magnetic body 220 is fixed on the first rotating component 200 and disposed on an end of the first magnetic body 210 in the second direction X. For example, one of two ends of the first magnetic body 210 is provided with at least one third magnetic body 220 (e.g., one or a plurality of third magnetic bodies 220), and the other end is provided with no third magnetic body 220. For another example, the two ends of the first magnetic body 210 are each provided with at least one third magnetic body 220.

The third magnetic component 220 has two magnetic poles configured in the first direction P (e.g., the direction indicated by the Z-axis in FIG. 11), and for the convenience of description, the two magnetic poles are referred to as a fifth magnetic pole 221 and a sixth magnetic pole 222, respectively. One of the two magnetic poles is opposite to the second magnetic body 610 in the second direction X. For example, the fifth magnetic pole 221 extends beyond the first magnetic body 210 in the first direction P, so that the fifth magnetic pole 221 is opposite to the second magnetic body 610 in the second direction X. The sixth magnetic pole 222 is opposite to the first magnetic body 210 in the second direction X, for example, may be in contact with the first magnetic body 210.

Polarities of two opposite poles of the third magnetic body 220 and the second magnetic body 610 are opposite. For example, in a third magnetic body 220_1, a fifth magnetic pole 221 is an N pole, and a sixth magnetic pole 222 is an S pole; the third magnetic pole 611 of the second magnetic body 610 is an S pole; and the first magnetic pole 211 of the first magnetic body 210 is an N pole. In a third magnetic element 220_2, a fifth magnetic pole 221 is an S pole, and a sixth magnetic pole 222 is an N pole; and the second magnetic pole 212 of the first magnetic body 210 is an S pole. For another example, in the third magnetic body 220_1, the fifth magnetic pole 221 is an S pole, and the sixth magnetic pole 222 is an N pole; the third magnetic pole 611 of the second magnetic body 610 is an N pole; and the first magnetic pole 211 of the first magnetic body 210 is an S pole. In the third magnetic element 220_2, the fifth magnetic pole 221 is an N pole, and the sixth magnetic pole 222 is an S pole; and the second magnetic pole 212 of the first magnetic body 210 is an N pole.

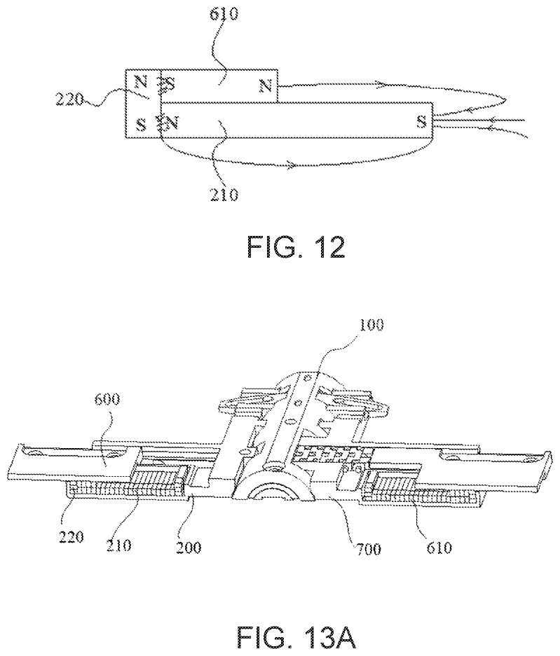

FIG. 12 is a distribution diagram of magnetic induction lines in a case where the flexible assembly is in an unfolded state or a bent state, in accordance with some embodiments. Referring to FIG. 12, the end of the first magnetic body 210 is provided with the third magnetic body 220, and when the second magnetic body 610 gradually slides to the end of the first magnetic body 210, magnetic induction lines inside the first magnetic body 210, the second magnetic body 610, and the third magnetic body 220 form a smoother closed magnetic field, a main part of the magnetic induction lines of the closed magnetic field are communicated, and the magnetic force is further enhanced, so that the first locking force is enhanced.

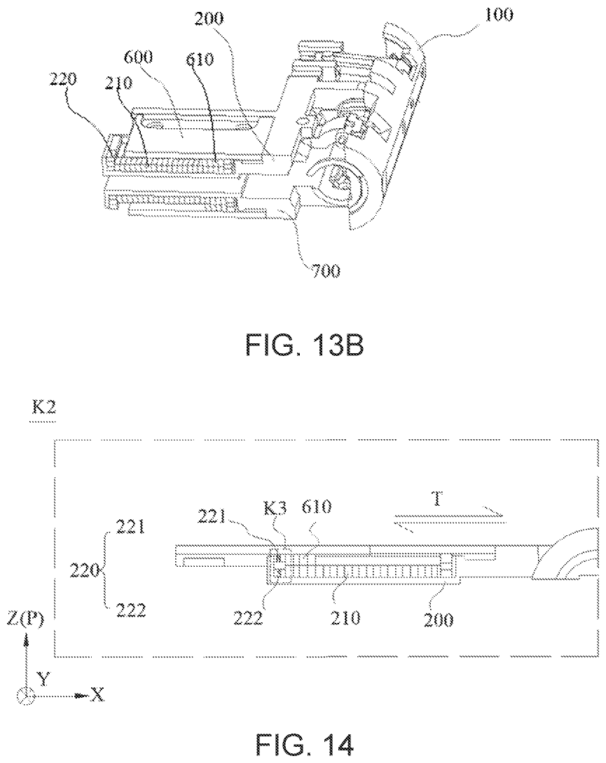

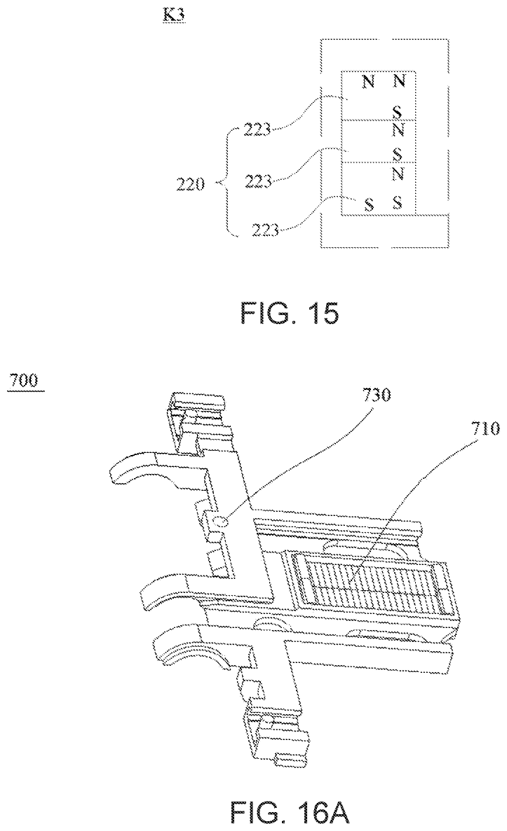

FIG. 13A is a perspective view of the flexible assembly in FIG. 9 in an unfolded state. FIG. 13B is a perspective view of the flexible assembly in FIG. 13A in a folded state. FIG. 14 is yet another alternative enlarged view of the region K2 in FIG. 4A. FIG. 15 is an enlarged view of the region K3 in FIG. 14. FIG. 16A is a structural diagram of the second rotating component in FIG. 7. FIG. 16B is a structural diagram of the first rotating component in FIG. 7. FIG. 16C is a structural diagram of the first sliding component in FIG. 7. Referring to FIGS. 13A, 13B, 14, 15, 16B and 16C, for example, the third magnetic body 220 includes a plurality of third magnetic units 223 stacked in the first direction P. For example, the plurality of third magnetic units 223 are sequentially formed in the first direction P. A magnetic pole direction of a third magnetic unit 223 (e.g., each third magnetic unit 223) is the same as a magnetic pole direction of the third magnetic body 220. For example, if the fifth magnetic pole 221 is an N pole and the sixth magnetic pole 222 is an S pole, a magnetic pole of each third magnetic unit 223 in the first direction P is an N pole and another magnetic pole of each third magnetic unit 223 in a direction opposite to the first direction P is an S pole. The embodiment can also achieve the effects of adjusting the first locking force, and the specific principle is approximately the same as that of the above embodiments, and details are not repeated here.

In one example, in the third magnetic body 220, each third magnetic unit 223 may be connected to the first rotating component 200 by a detachable assembly manner such as hot-melt adhesive bonding or clamping. In another example, in the third magnetic body 220, a part of the third magnetic units 223 is mounted on the first rotating component 200 by a detachable assembly manner, and another part of the third magnetic units 223 is fixed to the first rotating component 200 and cannot be detachable. For example, in FIG. 14, a lowermost third magnetic unit 223 may be fixed (detachably or non-detachably fixed) on the first rotating component 200, and each of other third magnetic units 223 may be bonded to an adjacent third magnetic unit 223 by hot-melt adhesive.

In other possible implementations, third magnetic body(s) 220 may also be fixed to an end (any end or two ends) of the second magnetic body 610. For example, one of the two ends of the second magnetic body 610 is provided with at least one third magnetic body 220 (e.g., one or a plurality of third magnetic bodies 220), and the other end is provided with no third magnetic body 220. For another example, the two ends of the second magnetic body 610 are each provided with at least one third magnetic body 220. The achieved effects are approximately similar to the effects of the above embodiments, and details will not be repeated here.

For example, referring to FIG. 16C, the first sliding component 600 is provided with mounting holes 630 therein. The intermediate connecting component IM (shown in FIG. 1) is provided therein with screw holes at positions connected to the first sliding component 600, and a screw hole is connected to a mounting hole 630 by a screw.

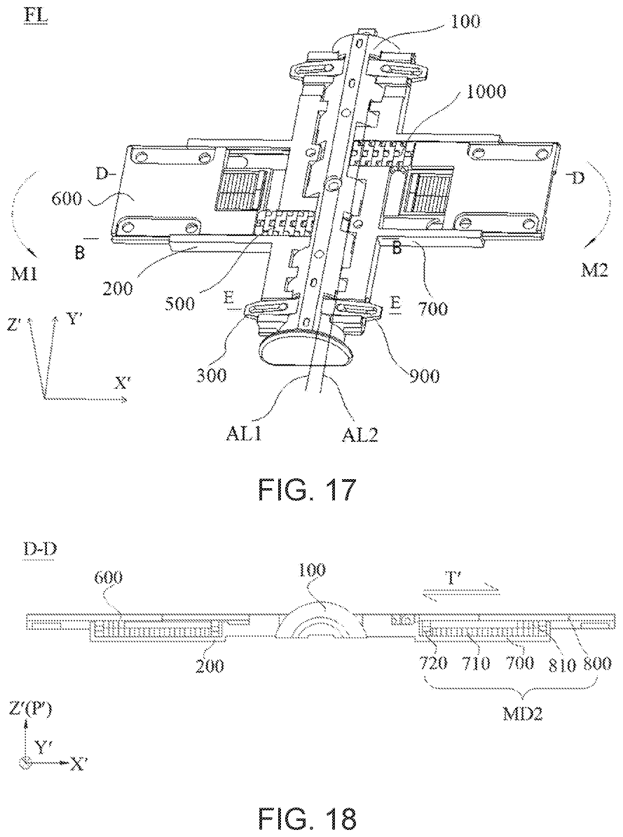

FIG. 17 is yet another alternative schematic diagram of FIG. 3. FIG. 18 is a sectional view taken along the line D-D in FIG. 17. Referring to FIGS. 17 to 18, some embodiments of the present disclosure provide a flexible assembly FL. The flexible assembly FL includes a second module MD2. The second module MD2 includes a second rotating component 700 and a second sliding component 800.

The second rotation component 700 is connected to the shaft body 100 and can rotate around an axis approximately parallel to the extending direction of the shaft body 100. Rotation directions of the second rotating component 700 and the first rotating component 200 are opposite. It can be noted that, the second rotating component 700 and the first rotating component 200 both rotate around the shaft body 100. The structure, material, etc. of the second rotating component 700 may refer to the first rotating component 200; of course, the two may be different.

The second sliding component 800 is connected to the second rotating component 700, and can reciprocate along a second linear path T′ relative to the second rotating component 700 (for example, a length direction of the second rotating component 700 is taken as an X′-axis, a width direction of the second rotating component 700 is taken as a Y′-axis, a thickness direction of the second rotating component 700 is taken as a Z′-axis, and the second linear path T′ is approximately parallel to a direction indicated by the X′-axis), so that the second sliding component 800 moves away from or close to the shaft body 100. That is, the second sliding component 800 slides back and forth along the second linear path T′ relative to the second rotating component 700.

In addition, as for the features of the connection structure between the second sliding component 800 and the second rotating component 700, reference may be made to the features of the connection structure between the first rotating component 200 and the first sliding component 600. In this way, in the flexible assembly FL, structures located on two side of the shaft body 100 are symmetrically distributed, which makes the flexible assembly FL more stable during bending. Of course, the features of the connection structure between the second sliding component 800 and the second rotating component 700 may be different from the features of the connection structure between the first rotating component 200 and the first sliding component 600.

With continued reference to FIGS. 17 to 18, for example, the flexible assembly FL further includes a fourth magnetic body 710 and a fifth magnetic body 810; the fourth magnetic body 710 is fixed to the second rotating component 700, and the fifth magnetic body 810 is fixed to the second sliding component 800; the second rotating component 700 moves along the second linear path T′, and the fourth magnetic body 710 and the fifth magnetic body 810 are positioned opposite to each other in a third direction P′ (in FIG. 17, an arbitrary direction within a Y′Z′ plane in an X′Y′Z′ Cartesian coordinate system). In this embodiment, as for the structures of the fourth magnetic body 710 and the fifth magnetic body 810 and the connection relationship and the position relationship between the fourth magnetic body 710 and the fifth magnetic body 810, reference may be made to the related description of the first magnetic body 210 and the second magnetic body 610 in the above embodiments. As for the connection relationship and the position relationship between the fourth magnetic body 710 and the second rotating component 700, reference may be made to the related description of the first magnetic component 210 and the first rotating component 200. As for the connection relationship and the position relationship between the fifth magnetic body 810 and the second sliding component 800, reference may be made to the related description of the second magnetic body 610 and the first sliding component 600. The achieved effects are same as the effects of the above embodiments, which will not be repeated here.

In addition, in a case where the second sliding component 800 moves to an end of the second linear path T′, a second locking force is created between the fourth magnetic body 710 and the fifth magnetic body 810; in a case where the second sliding component 800 moves to a middle of the second linear path, an attractive force between the fourth magnetic body 710 and the fifth magnetic body 810 is smaller than the second locking force. As for the related description of the second locking force in this embodiment, reference may be made to the first locking force in the above embodiments. The achieved effects are same as the effects of the above embodiments, which will not be repeated here.

With continued reference to FIGS. 17 to 18, some embodiments of the present disclosure provide a flexible assembly FL. The flexible assembly FL further includes a sixth magnetic body 720. Similarly, the sixth magnetic body 720 may be one or a combination of more of a permanent magnet, an electromagnet and the like.

In some possible implementations, the sixth magnetic body 720 is fixed on the second rotating component 700, and is disposed on an end of the fourth magnetic body 710 in the third direction P′. For example, any one end of two ends of the fourth magnetic body 710 is provided with at least one sixth magnetic body 720 (e.g., one or a plurality of sixth magnetic bodies 720), and the other end is provided with no sixth magnetic body 720. For another example, the two ends of the fourth magnetic body 710 are each provided with at least one sixth magnetic body 720. In this embodiment, as for the positional relationship between magnetic poles of the sixth magnetic body 720 and the fourth magnetic body 710, reference may be made to the positional relationship between the magnetic poles of the third magnetic body 220 and the first magnetic body 210 in the above embodiments. As for the related description of the relationship between the magnetic poles of the sixth magnetic body 720 and the fifth magnetic body 810, reference may be made to the related description of the magnetic poles of the third magnetic body 220 and the second magnetic body 610 in the above embodiments. The achieved effects are same as the effects of the above embodiments, which will not be repeated here.

With continued reference to FIGS. 17 to 18, for example, any one, any two, or three of the fourth magnetic body 710, the sixth magnetic body 720 and the fifth magnetic body 810 may each include a plurality of magnetic units. The related description of this embodiment may refer to that of the above embodiments, and the achieved effects are the same as the effects of the above embodiments, which will not be repeated here.

With continued reference to FIGS. 17 to 18, some embodiments of the present disclosure provide a flexible assembly FL, and the flexible assembly FL further includes a first flexible connecting component 500. An end of the first flexible connecting component 500 is connected to the second rotating component 700, and another end of the first flexible connecting component 500 is connected to the first sliding component 600. That is, by the first flexible connecting component 500, the second rotating component 700 and the first sliding component 600 that are located on different sides of the shaft body 100 are connected. Therefore, when the second rotating component 700 rotates around the shaft body 100, the second rotating component 700 drives the first sliding component 600 to slide relative to the first rotating component 200.

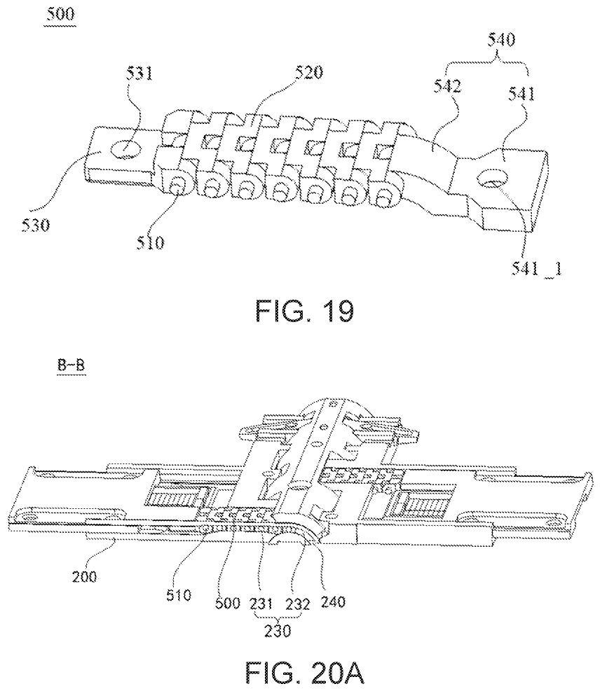

FIG. 19 is a three-dimensional structural diagram of the first flexible connecting component in FIG. 17. Referring to FIG. 19, for example, the first flexible connecting component 500 is a chain including a plurality of pin shafts 510 and a plurality of chain links 520; among the plurality of chain links 520, two adjacent chain links 520 are connected by a pin shaft 510. Two ends of the first flexible connecting component 500 are fixedly connected to the second rotating component 700 and the first sliding component 600, respectively.

Referring to FIGS. 16A, 16B, 17 and 19, in some possible embodiments, an end of the first flexible connecting component 500 is provided with a first connecting link 530 and another end of the first flexible connecting component 500 is provided with a second connecting link 540. The first connecting link 530 and a chain link 520 that is located on an end are connected as a whole, and the first connecting link 530 is provided therein with a first connecting hole 531. The first sliding component 600 is provided with a first connecting pin 620 at a position thereof connected to the first flexible connecting component 500. The first connecting pin 620 is clamped in the first connecting hole 531, and the two are further fixed by welding, which makes the connection more stable.

The second connecting link 540 includes a rectangle portion 541 and an arc portion 542 that are connected as a whole, and the arc portion 542 is connected to a chain link 520 at an end by a pin shaft 510. The rectangle portion 541 is provided therein with a second connecting hole 541_1. The second rotating component 700 is provided therein with a screw hole 730 at a position thereof connected to the first flexible connecting component 500, and the screw hole 730 is connected to the second connecting hole 541_1 by a screw.

In some other possible implementations, the two ends of the first flexible connecting component 500 are provided therein with screw holes, and the second rotating component 700 and the first sliding component 600 are provided therein with screw holes corresponding to positions thereof connected to the first flexible connecting component 500. The screw hole of the second rotation component 700 is connected to a screw hole of the first flexible connecting component 500 by a screw, and the screw hole of the first sliding component 600 is connected to a screw hole of the first flexible connecting component 500 by a screw.

For another example, the first flexible connecting component 500 may be a flexible connecting strip, such as a rubber strip or the like.

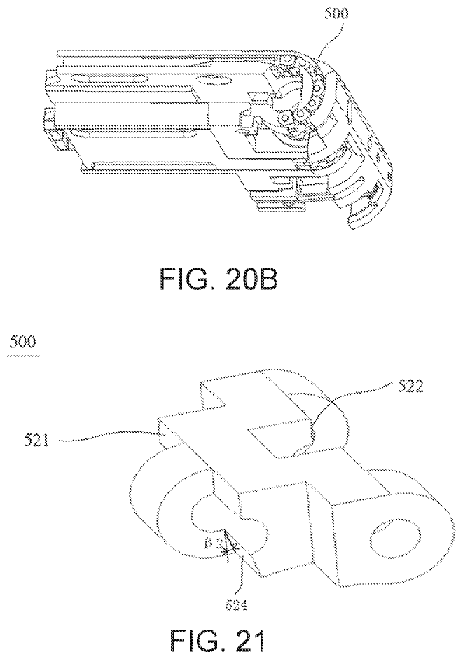

FIG. 20A is a sectional view taken along the line B-B in FIG. 17. FIG. 20B is a schematic diagram of a structure in FIG. 20A in a folded state. Referring to FIGS. 20A to 20B, for example, the first flexible connecting component 500 moves synchronously with the bending or unfolding of the flexible assembly FL. However, the first flexible connecting component 500 has a great degree of freedom. In this way, dead point(s) may occur in the first flexible connecting component 500 during the movement, resulting in jamming of the first flexible connecting component 500 during the movement. Therefore, in this embodiment, the first rotating component 200 has a first guiding structure 230 matched with the first flexible connecting component 500, and a guiding direction of the first guiding structure 230 is approximately parallel to the first linear path T (shown in FIG. 4C). In this way, when the first flexible connecting component 500 moves due to the guiding action of the first guiding structure 230, the first guiding structure 230 limits the degree of freedom of the first flexible connecting component 500, which can avoid the jamming of the first flexible connecting component 500 during the movement.

With continued reference to FIG. 20A, in some possible implementations, the first guiding structure 230 includes a first protruding portion 231 and a first sliding groove 232. The first protruding portion 231 is a portion of a pin shaft 510 that protrudes from a sidewall of a chain link 520 (shown in FIG. 19). The first rotating component 200 is provided therein with a first mounting groove 240 for mounting the first flexible connecting component 500, a sidewall of the first mounting groove 240 is provided with the first sliding groove 232, and the first protruding portion 231 slides in the first sliding groove 232.

In other possible implementations, the first guiding structure 230 includes a second protruding portion and a guiding platform. The second protruding portion is a portion of a pin shaft 510 that protrudes from a sidewall of a chain link 520 (shown in FIG. 19). In addition, the second protruding portion is provided therein with a sliding groove. The first rotating component 200 is provided with a second mounting groove for mounting the first flexible connecting component 500, and a sidewall of the second mounting groove is provided with the guiding platform. The guiding platform is located in the sliding groove of the second protruding portion, thereby constituting a sliding pair. Therefore, the groove of the second protruding portion slides back and forth along the guiding platform.

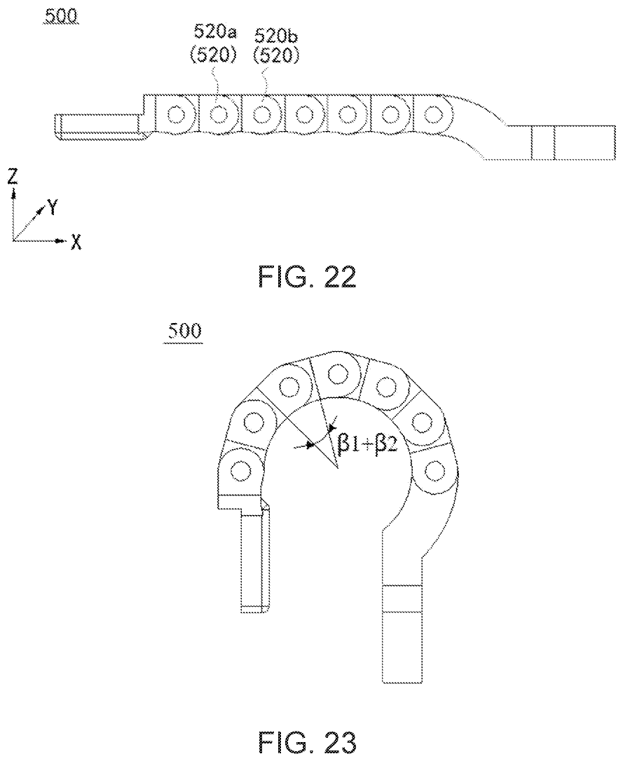

FIG. 21 is a structural diagram of the chain link in FIG. 19. FIG. 22 is a schematic diagram of the first flexible connecting component in FIG. 19 in an unfolded state. For example, referring to FIGS. 21 to 22, a chain link 520 (each chain link 520) of the first flexible connecting component 500 includes a first flat limiting surface 521 and a second flat limiting surface 522 that are opposite to each other in an arrangement direction of the plurality of chain links. That is, a projection, on the YZ plane, of the first flat limiting surface 521 along the second direction X and a projection, on the YZ plane, of the second flat limiting surface 522 along the second direction X at least partially (partially or completely) overlap. The first flat limiting surface 521 is parallel to the second flat limiting surface 522.

In addition, when the first flexible connecting component 500 is in an unfolded state, for convenience of the following description, two adjacent chain links 520 are respectively referred to as a first chain link 520a and a second chain link 520b, and a first flat limiting surface 521 of one of the two adjacent chain links 520 and a second flat limiting surface 522 of the other of the two adjacent chain links 520 can abut against each other. For example, the first flat limiting surface 521 of the first chain link 520a and the second flat limiting surface 522 of the second chain link 520b can abut against each other. For another example, the second flat limiting surface 522 of the first chain link 520a and the first flat limiting surface 521 of the second chain link 520b can abut against each other. In this way, a shape of the first flexible connecting component 500 in an unfolded state may be kept (that is, the flexible assembly FL and the flexible screen FS are in an unfolded state), and the first flexible connecting component 500 maintains in an unfolded state all the time, so as to prevent the first flexible connecting component 500 from being folded back.

With continued reference to FIGS. 21 to 22, for example, when the first flexible connecting component 500 is in an unfolded state, a plane where the first flat limiting surface 521 is located is approximately perpendicular to a plane where the first flexible connecting component 500 is located, which makes the limiting of the unfolded state more stable.

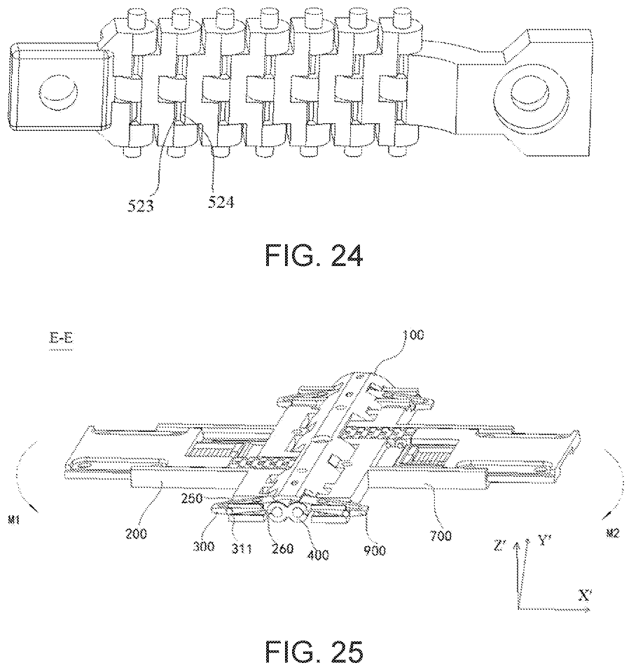

FIG. 23 is a schematic diagram of the first flexible connecting component in FIG. 19 in a folded state. FIG. 24 is a schematic diagram of a backside of the first flexible connecting component in FIG. 19 in an unfolded state. Referring to FIGS. 22 to 24, some embodiments of the present disclosure provide a flexible assembly FL. The chain link 520 includes a first bent limiting surface 523 and a second bent limiting surface 524 that are opposite to each other in the arrangement direction of the plurality of chain links. That is, a projection, on the YZ plane, of the first bent limiting surface 523 along the second direction X and a projection, on the YZ plane, of the second bent limiting surface 524 along the second direction X at least partially (partially or completely) overlap.

In addition, when the first flexible connecting component 500 is in a bent state, a first bent limiting surface 523 of one of the two adjacent chain links 520 (the first chain link 520a and the second chain link 520b) and a second bent limiting surface 524 of the other of the two adjacent chain links 520 can abut against each other. For example, the first bent limiting surface 523 of the first chain link 520a and the second bent limiting surface 524 of the second chain link 520b can abut against each other. For another example, the second bent limiting surface 524 of the first chain link 520a and the first bent limiting surface 523 of the second chain link 520b can abut against each other.

The first bent limiting surface 523 and the second bent limiting surface 524 are both obliquely arranged. An included angle between the second bent limiting surface 524 and a plane of the unfolded first flexible connecting component 500 is marked as β2 (shown in FIG. 21), an included angle between the first bent limiting surface 523 and the plane of the unfolded first flexible connecting component 500 (a plane where the first flexible connecting component 500 is in an unfolded state) is marked as β1 (which is arranged corresponding to β2 and not shown in the figure), the first included angle β1 and the second included angle β2 are approximately equal, and the calculation formulas of the first included angle β1 and the second included angle β2 are as follows: β1=γ/(n−1) and β2=γ/(n−1); here, n is the number of the chain links 520, and γ is the maximum bent angle of the display device DI. In this way, a shape of the first flexible connecting component 500 in a folded state may be kept (that is, the flexible assembly FL and the flexible screen FS are in a folded state), and the first flexible connecting component 500 maintains in a folded state all the time, so as to prevent the first flexible connecting component 500 from being over-folded.

With continued reference to FIG. 17, some embodiments of the present disclosure provide a flexible assembly FL. The flexible assembly FL further includes a second flexible connecting component 1000, an end of the second flexible connecting component 1000 is connected to the first rotating component 200, and another end of the second flexible connecting component 1000 is connected to the second sliding component 800. The related description of this embodiment may refer to the above embodiments, and the achieved effects are approximately the same as the effects of the above embodiments, which are not repeated here.

FIG. 25 is a sectional view taken along the line E-E in FIG. 17. Referring to FIG. 25, some embodiments of the present disclosure provide a flexible assembly FL, and the first rotating component 200 and the second rotating component 700 can rotate synchronously in opposite directions around the shaft body 100. For example, the first rotating component 200 rotates around the shaft body 100 in a counterclockwise direction M1, and the second rotating component 700 rotates around the shaft body 100 in a clockwise direction M2. Of course, the rotation directions of the first rotating component 200 and the second rotating component 700 may be interchanged. In this way, the internal stress of flexible assembly FL is even, which avoids the damage of the flexible assembly FL caused by the uneven stress, and in turn improves the lifetime of the flexible assembly FL.

For example, the flexible assembly FL further includes a first drive gear wheel 300 and a second drive gear wheel 900. The first drive gear wheel 300 and the first rotating component 200 are linked. That is, the first drive gear wheel 300 and the first rotating component 200 rotate simultaneously around the shaft body 100 in the same rotation direction. The second drive gear wheel 900 and the second rotating component 700 are linked. That is, the second drive gear wheel 900 and the second rotating component 700 rotate simultaneously around the shaft body 100 in the same rotation direction. The first drive gear wheel 300 and the second drive gear wheel 900 are each pivotally connected to the shaft body 100, and the first drive gear wheel 300 and the second drive gear wheel 900 are engaged with each other. Therefore, the first drive gear wheel 300 and the second drive gear wheel 900 rotate synchronously around the shaft body 100 in opposite directions, and the first rotating component 200 and second rotating component 700 can rotate synchronously around the shaft body 100 in opposite directions.

With continued reference to FIG. 25, for example, an axis of the first rotating component 200 rotating around the shaft body 100 does not coincide with an axis of the first drive gear wheel 300 rotating around the shaft body 100. For convenience of the following description, the axis of rotation of the first rotating component 200 is denoted as AL1 (shown in FIG. 17), and the axis of rotation of the first drive gear wheel 300 is denoted as AL2 (shown in FIG. 17). The first drive gear wheel 300 is slidably connected to the first rotating component 200. In this way, during the synchronous rotation of both the first rotating component 200 and the first drive gear wheel 300, it is possible to compensate for the position offset between the first rotating component 200 and the first drive gear wheel 300 caused by the deviation of the axes AL1 and AL2.

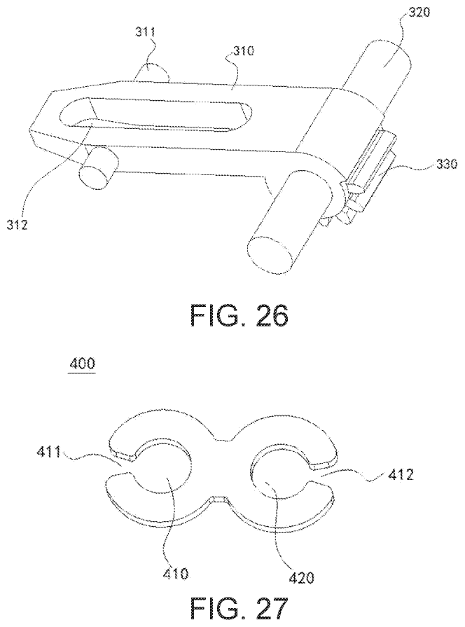

FIG. 26 is a structural diagram of the first drive gear wheel in FIG. 17. Referring to FIGS. 25 to 26, for example, the first drive gear wheel 300 includes a connecting plate 310, a connecting shaft 320, and a plurality of teeth 330. The connecting shaft 320 is pivotally connected to the shaft body 100. The plurality of teeth 330 are distributed along a circumferential direction of the connecting shaft 320. The connecting plate 310 is fixedly connected to the connecting shaft 320, and extends in a direction parallel to a radial direction of the connecting shaft 320. The structure of the second drive gear wheel 900 is approximately the same as that of the first drive gear wheel 300, and the second drive gear wheel 900 and the first drive gear wheel 300 are engaged by the plurality of teeth 330 thereof. Therefore, the first drive gear wheel 300 and the second drive gear wheel 900 rotate synchronously, and the first rotating component 200 and the second rotating component 700 rotate synchronously.

In conjunction with FIGS. 16B, 16C and 26, the first rotating component 200 has a sliding rail 250, and an extending direction of the sliding rail 250 is approximately parallel to the first linear path T (shown in FIG. 4C). The connecting plate 310 has a sliding block 311 capable of sliding along the sliding rail 250.

With continued reference to FIGS. 25 to 26, for example, in FIG. 26, the connecting plate 310 is provided therein with a limiting groove 312, and the limiting groove 312 extends in the direction parallel to the radial direction of the connecting shaft 320. In FIG. 25, the first rotating component 200 further has a limiting portion 260 capable of sliding in the limiting groove 312. In this way, it may constraint that when the first drive gear wheel 300 and the first rotating component 200 rotate around the shaft body 100, the first drive gear wheel 300 shakes back and forth in the direction approximately parallel to the axis of the shaft body 100, which affects the smoothness of rotation of the first drive gear wheel 300 and the first rotating component 200.

For another example, an axis of the second rotating component 700 rotating around the shaft body 100 does not coincide with an axis of the second drive gear wheel 900 rotating around the shaft body 100, and the second drive gear wheel 900 is slidably connected to the second rotating component 700. As for the structures and the connection structure of the second drive gear wheel 900 and the second rotating component 700, reference may be made to the related description of the first drive gear wheel and the first rotating component.

For another example, the axis of the first rotating component 200 rotating around the shaft body 100 does not coincide with the axis of the first drive gear wheel 300 rotating around the shaft body 100, and the first drive gear wheel 300 is slidably connected to the first rotating component 200. The axis of the second rotating component 700 rotating around the shaft body 100 does not coincide with the axis of the second drive gear wheel 900 rotating around the shaft body 100, and the second drive gear wheel 900 is slidably connected to the second rotating component 700.

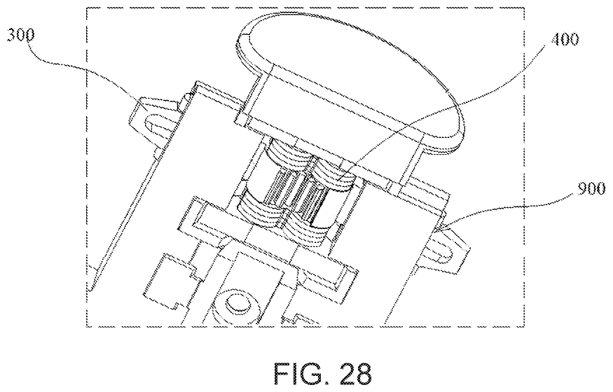

FIG. 27 is a structural diagram of a torque plate in FIG. 25; Referring to FIGS. 25 and 27, in some embodiments, the flexible assembly FL further includes torque plate(s) 400. The torque plate 400 has a first hole 410 and a second hole 420. The first drive gear wheel 300 is pivotally connected to the first hole 410, and the second drive gear wheel 900 is pivotally connected to the second hole 420. For example, the first hole 410 of the torque plate 400 is sleeved on the connecting shaft 320 of the first drive gear wheel 300, and the second hole 420 of the torque plate 400 is sleeved on the connecting shaft of the second drive gear wheel 900, so that the torque plate 400 contacts with sidewalls of the first drive gear wheel 300 and the second drive gear wheel 900 to create friction forces, and damping forces are created. Therefore, the flexible assembly FL does not shake back and forth after being bent at any angle, and the position is kept to be fixed, that is, the flexible assembly FL stops at any angle at any time.

For example, the first hole 410 and the second hole 420 of the torque plate 400 are both circular arc sheet-shaped structures, and are connected as a whole.

For example, the torque plate 400 is provided therein with a first opening 411 communicated with the first hole 410; therefore, an expansion amount due to heat generated during the friction process of the torque plate 400 and the first drive gear wheel 300 may be offset.

In addition, the first opening 411 is a circular hole, the first opening 411 is disposed at a center of the first hole 410, and the first opening 411 and the first hole 410 are concentrically arranged, so that the stress is more uniform.

For example, the torque plate 400 is provided therein with a second opening 412 communicated with the second hole 420. In addition, the second opening 412 is a circular hole, and the second opening 412 is disposed at a center of the second hole 420, and the second opening 412 and the second hole 420 are concentrically arranged. The effects achieved by this embodiment are approximately the same as the effects achieved by the above embodiments, which will not be repeated here.

For example, the torque plate 400 is provided therein with the first opening 411 communicated with the first hole 410, and the torque plate 400 is provided therein with the second opening 412 communicated with the second hole 420. The effects achieved by this embodiment are approximately the same as the effects achieved by the above embodiments, which will not be repeated here.

FIG. 28 is a partial enlarged view of a bottom of the structure shown in FIG. 3. In some embodiments, referring to FIG. 28, a plurality of torque plates 400 may be sleeved on each of the first drive gear wheel 300 and the second drive gear wheel 900, and the plurality of torque plates 400 are sequentially sleeved on each of the connecting shaft of the first drive gear wheel 300 and the connecting shaft of the second drive gear wheel 900.

The foregoing descriptions are merely specific implementations of the present disclosure, but the protection scope of the present disclosure is not limited thereto. Any changes or replacements that a person skilled in the art could readily conceive of within the technical scope of the present disclosure shall be included in the protection scope of the present disclosure. Therefore, the protection scope of the present disclosure shall be subject to the protection scope of the claims.

1. A flexible assembly, comprising:
a shaft body;
a first rotating component rotatably connected to the shaft body;
a first sliding component connected to the first rotating component and capable of reciprocating along a first linear path relative to the first rotating component, so that the first sliding component is far away from or close to the shaft body; and
a first magnetic body and a second magnetic body, wherein the first magnetic body is fixed on the first rotating component, the second magnetic body is fixed on the first sliding component, and the first magnetic body and the second magnetic body are opposite to each other in a first direction as the first sliding component moves along the first linear path relative to the first rotating component, the first direction being approximately perpendicular to the first linear path;
wherein in a case where the first sliding component moves to an end of the first linear path, a first locking force is created between the first magnetic body and the second magnetic body; and in a case where the first sliding component moves to a middle of the first linear path, an attractive force between the first magnetic body and the second magnetic body is smaller than the first locking force.

2. The flexible assembly according to claim 1, wherein
the first magnetic body includes a plurality of first magnetic units arranged in a second direction, and magnetic pole directions of the first magnetic units are the same as a magnetic pole direction of the first magnetic body, the second direction being approximately parallel to the first linear path.

3. The flexible assembly according to claim 2, wherein
at least one first magnetic unit of the first magnetic body is detachably connected to the first rotating component.

4. The flexible assembly according to claim 1, wherein
the second magnetic body includes a plurality of second magnetic units arranged in a second direction, and a magnetic pole direction of a second magnetic unit of the plurality of second magnetic units is the same as a magnetic pole direction of the second magnetic body, the second direction being approximately parallel to the first linear path.

5. The flexible assembly according to claim 1, wherein
the first magnetic body and the second magnetic body each have two magnetic poles configured in a second direction, the second direction being approximately parallel to the first linear path.

6. The flexible assembly according to claim 5, wherein the first magnetic body and the second magnetic body have opposite magnetic pole directions and unequal lengths; and/or
a length of one of the first magnetic body and the second magnetic body is less than a half of a length of another of the first magnetic body and the second magnetic body.

7. (canceled)

8. The flexible assembly according to claim 1, further comprising:
a third magnetic body fixed on the first rotating component and disposed on an end of the first magnetic body in a second direction, wherein the third magnetic body has two magnetic poles configured in the first direction, one of the two magnetic poles is opposite to the second magnetic body in the second direction, and a magnetic pole of the third magnetic body and a magnetic pole of the second magnetic body that are opposite to each other have opposite polarities, the second direction being approximately parallel to the first linear path.

9. The flexible assembly according to claim 8, wherein
the third magnetic body includes a plurality of third magnetic units stacked in the first direction, and a magnetic pole direction of a third magnetic unit of the plurality of third magnetic units is the same as a magnetic pole direction of the third magnetic body.

10. The flexible assembly according to claim 1, further comprising:
a second rotating component rotatably connected to the shaft body, wherein the second rotating component and the first rotating component rotate in opposite directions; and
a second sliding component connected to the second rotating component and capable of reciprocating along a second linear path relative to the second rotating component, so that the second sliding component is far away from or close to the shaft body.

11. The flexible assembly according to claim 10, further comprising:
a fourth magnetic body and a fifth magnetic body, wherein the fourth magnetic body is fixed on the second rotating component, the fifth magnetic body is fixed on the second sliding component, and the fourth magnetic body and the fifth magnetic body are opposite to each other in a third direction as the second sliding component moves along the second linear path relative to the second rotating component, the third direction being approximately perpendicular to the second linear path;
wherein in a case where the second sliding component moves to an end of the second linear path, a second locking force is created between the fourth magnetic body and the fifth magnetic body; and in a case where the second sliding component moves to a middle of the second linear path, an attractive force between the fourth magnetic body and the fifth magnetic body is smaller than the second locking force.

12. The flexible assembly according to claim 10, further comprising:
a first flexible connecting component, wherein an end of the first flexible connecting component is connected to the second rotating component, and another end of the first flexible connecting component is connected to the first sliding component.

13. The flexible assembly according to claim 12, wherein
the first rotating component is provided therein with a first guiding structure matched with the first flexible connecting component, and a guiding direction of the first guiding structure is approximately parallel to the first linear path; and/or
the first flexible connecting component includes a plurality of pin shafts and a plurality of chain links, and two adjacent chain links in the plurality of chain links are connected through a pin shaft of the plurality of pin shafts.

14. (canceled)

15. The flexible assembly according to claim 13, wherein
each chain link of the plurality of chain links includes a first flat limiting surface and a second flat limiting surface that are opposite and parallel to each other in an arrangement direction of the plurality of chain links;
in a case where the first flexible connecting component is in an unfolded state, a first flat limiting surface of one of the two adjacent chain links and a second flat limiting surface of another of the two adjacent chain links are able to abut against each other, or the first flat limiting surface of one of the two adjacent chain links and the second flat limiting surface of another of the two adjacent chain links are able to abut against each other and the first flat limiting surface of each chain link is approximately perpendicular to a plane where the first flexible connecting component is located;
and/or
each chain link of the plurality of chain links includes a first bent limiting surface and a second bent limiting surface that are opposite to each other in an arrangement direction of the plurality of chain links; and in a case where the first flexible connecting component is in a folded state, a first bent limiting surface of one of the two adjacent chain links and a second bent limiting surface of another of the two adjacent chain links are able to abut against each other.

16-17. (canceled)

18. The flexible assembly according to claim 10, further comprising:
a second flexible connecting component, wherein an end of the second flexible connecting component is connected to the first rotating component, and another end of the second flexible connecting component is connected to the second sliding component; and/or
the first rotating component and the second rotating component are able to synchronously rotate around the shaft body in opposite directions.

19. (canceled)

20. The flexible assembly according to claim 10, further comprising:
a first drive gear wheel linked to the first rotating component; and
a second drive gear wheel linked to the second rotating component;
wherein the first drive gear wheel and the second drive gear wheel are each pivotally connected to the shaft body, and are engaged with each other; and the first rotating component and the second rotating component are able to synchronously rotate around the shaft body in opposite directions.

21. The flexible assembly according to claim 20, wherein
an axis of the first rotating component rotating around the shaft body does not coincide with an axis of the first drive gear wheel rotating around the shaft body, and the first drive gear wheel is slidably connected to the first rotating component; and/or
an axis of the second rotating component rotating around the shaft body does not coincide with an axis of the second drive gear wheel rotating around the shaft body, and the second drive gear wheel is slidably connected to the second rotating component.

22. The flexible assembly according to claim 21, wherein
the first drive gear wheel includes:
a connecting shaft pivotally connected to the shaft body;
a plurality of teeth distributed in a circumferential direction of the connecting shaft; and
a connecting plate fixedly connected to the connecting shaft and extending in a direction parallel to a radial direction of the connecting shaft;
wherein the first rotating component has a sliding rail, and an extending direction of the sliding rail is approximately parallel to the first linear path; and the connecting plate has a sliding block capable of sliding along the sliding rail.

23. The flexible assembly according to claim 22, wherein
the connecting plate is provided therein with a limiting groove, and the limiting groove extends in the direction parallel to the radial direction of the connecting shaft; and the first rotating component further has a limiting portion capable of sliding in the limiting groove.

24. The flexible assembly according to claim 20, further comprising:
a torque plate having a first hole and a second hole, wherein
the first drive gear wheel is pivotally connected to the first hole, and the second drive gear wheel is pivotally connected to the second hole; or
wherein the first drive gear wheel is pivotally connected to the first hole, and the second drive gear wheel is pivotally connected to the second hole; and the torque plate is provided therein with a first opening communicated with the first hole, and/or the torque plate is provided therein with a second opening communicated with the second hole.

25. (canceled)

26. A display device, comprising:
the flexible assembly according to claim 1; and
a flexible display screen, wherein the flexible display screen is connected to the first sliding component in the flexible assembly.
